(19) United States
(12) Patent Application Publication
(10) Pub. No.: US 2023/0298937 A1
(43) Pub. Date: Sep. 21, 2023

(54) SEMICONDUCTOR DEVICE INCLUDING THROUGH VIAS WITH DIFFERENT WIDTHS AND METHOD OF MANUFACTURING THE SAME

(71) Applicant: SK hynix Inc., Icheon-si Gyeonggi-do (KR)

(72) Inventors: Jin Woong KIM, Icheon-si Gyeonggi-do (KR); Ju Heon YANG, Icheon-si Gyeonggi-do (KR)

(73) Assignee: SK hynix Inc., Icheon-si Gyeonggi-do (KR)

(21) Appl. No.: 17/962,687

(22) Filed: Oct. 10, 2022

(30) Foreign Application Priority Data
Mar. 16, 2022 (KR) 10-2022-0033024

(51) Int. Cl. H01L 21/768; H01L 23/48

(52) U.S. Cl. CPC H01L 21/76898; H01L 23/481; H01L 21/7684; H01L 2224/13147; H01L 24/13

(57) ABSTRACT

There is provided a semiconductor device including through vias and a method of manufacturing the same. The semiconductor device includes a substrate including a first via hole and a second via hole, a first through via formed in the first via hole, a second through via formed in the second via hole, an insulating layer first portion formed between a sidewall surface of the first via hole and the first through via, and an insulating layer second portion formed between a sidewall surface of the second via hole and the second through via. The insulating layer second portion is thinner than the insulating layer first portion, and the second through via is wider than the first through via,

### CROSS-REFERENCE TO RELATED APPLICATION

The present application claims priority under 35 U.S.C. 119(a) to Korean Application No. 10-2022-0033024, filed on Mar. 16, 2022, which is incorporated herein by reference in its entirety.

### BACKGROUND

### 1. Technical Field

The present disclosure generally relates to a semiconductor device, and more particularly, to a semiconductor device including through vias with different widths and a method of manufacturing the same.

### 2. Related Art

Integrated circuits may be integrated on a semiconductor substrate to configure a semiconductor device. The integrated circuits may be configured to include a plurality of electronic components. The electronic components may include transistors, capacitors, resistors, and/or diodes. As the semiconductor devices are required to include a greater number of integrated circuits or electronic components, attempts are being made to configure the integrated circuits in semiconductor devices in three dimensions. At least two semiconductor dies are stacked to configure semiconductor devices, thereby configuring three-dimensional integrated circuits in the semiconductor devices. In order to three-dimensionally connect the stacked semiconductor dies without wire bonding, the semiconductor devices may include through vias.

### SUMMARY

In accordance with the present disclosure is a method of manufacturing a semiconductor device. The method may include forming a first via hole and a second via hole in a substrate; forming an insulating layer including a first portion and a second portion, the first portion narrowing the first via hole to a third via hole and the second portion narrowing the second via hole to a fourth via hole; reducing a thickness of the second portion of the insulating layer to increase a width of the fourth via hole; and forming a first through via and a second through via, the first through via filling the third via hole and the second through via filling the fourth via of increased width.

In accordance with an embodiment of the present disclosure is a semiconductor device including: a substrate including first via hole and a second via hole; a first through via formed in the first via hole; a second through via formed in the second via hole; an insulating layer first portion formed between a sidewall surface of the first via hole and the first through via; and an insulating layer second portion formed between a sidewall surface of the second via hole and the second through via. The insulating layer second portion is thinner than the insulating layer first portion, and the second through via is wider than the first through via.

In accordance with the present disclosure is a method of manufacturing a semiconductor device. The method may include forming a first via hole and a second via hole in a substrate; forming a first insulating layer including a first portion and a second portion, the first portion narrowing the first via hole to a third via hole and the second portion narrowing the second via hole to a fourth via hole; forming a second insulating layer overlapping the first portion of the first insulating layer narrowing the third via hole to a fifth via hole; and forming a first through via filling the fifth through via and a second through via filling the fourth via hole.

In accordance with an embodiment of the present disclosure is a semiconductor device including: a substrate including a first via hole and a second via hole; a first through via formed in the first via hole; a second through via formed in the second via hole; a first insulating layer first portion and a second insulating layer formed between a sidewall surface of the first via hole and the first through via; and a first insulating layer second portion formed between a sidewall surface of the second via hole and the second through via. The second through via is wider than the first through via.

### BRIEF DESCRIPTION OF THE DRAWINGS

FIGS. 1 to 14 are schematic diagrams illustrating a semiconductor device according to an embodiment of the present disclosure and a method of manufacturing the same.

FIG. 15 is a schematic diagram illustrating a semiconductor device according to another embodiment of the present disclosure.

FIGS. 16 to 27 are schematic diagrams illustrating a semiconductor device according to another embodiment of the present disclosure and a method of manufacturing the same.

FIG. 28 is a schematic diagram illustrating a semiconductor device according to further another embodiment of the present disclosure.

FIG. 29 is a block diagram illustrating an electronic system employing a memory card including a semiconductor device in accordance with an embodiment of the present disclosure.

FIG. 30 is a block diagram illustrating an electronic system including a semiconductor device according to an embodiment of the present disclosure.

### DETAILED DESCRIPTION

The terms used herein may correspond to words selected in consideration of their functions in presented embodiments, and the meanings of the terms may be construed to be different according to one of ordinary skill in the art to which the embodiments belong. If defined in detail, the terms may be construed according to the definitions, Unless otherwise defined, the terms (including technical and scientific terms) used herein have the same meaning as commonly understood by one of ordinary skill in the art to which the embodiments belong.

It will be understood that although the terms “first” and “second,” “side,” “top,” and “bottom or lower” may be used herein to describe various devices, these devices should not be limited by these terms. These terms are only used to distinguish one device from another device, but not used to indicate a particular sequence or number of devices,

A semiconductor substrate may refer to a semiconductor wafer, a semiconductor die, or a semiconductor chip in which electronic components and devices are integrated. The semiconductor chip may refer to a memory chip in which memory integrated circuits, such as dynamic random access memory (DRAM) circuits, static random access memory (SRAM) circuits, NAND-type flash memory circuits, NOR-type flash memory circuits, magnetic random access memory (MRAM) circuits, resistive random access memory (ReRAM) circuits, ferroelectric random access memory (FeRAM) circuits, or phase change random access memory (PcRAM) are integrated, logic dies or ASIC chips in which logic circuits are integrated in a semiconductor substrate, or processors, such as application processors (Aps), graphic processing units (GPUs), central processing units (CPUs) or system-on-chips (SoCs). The semiconductor device may be employed in information communication systems, such as mobile phones, electronic systems associated with biotechnology or health care, or wearable electronic systems. The semiconductor device may be applicable to internet of things (IoT).

Same reference numerals refer to same devices throughout the specification. Even though a reference numeral might not be mentioned or described with reference to a drawing, the reference numeral may be mentioned or described with reference to another drawing. In addition, even though a reference numeral might not be shown in a drawing, it may be shown in another drawing.

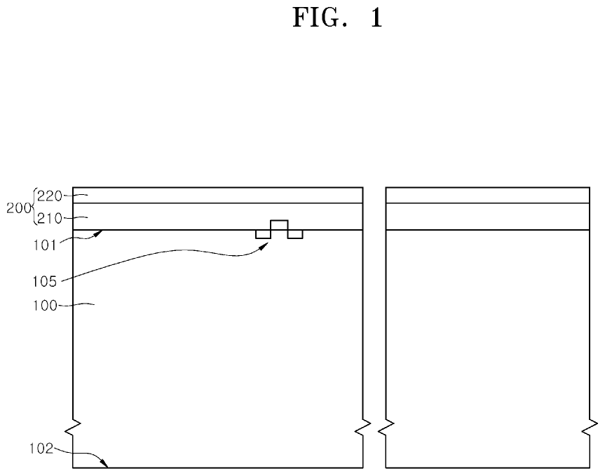

FIGS. 1 to 14 are schematic diagrams illustrating a semiconductor device according to an embodiment of the present disclosure and a method of manufacturing the same.

Referring to FIG, 1, a dielectric layer 200 may be formed on a substrate 100. The substrate 100 may be a semiconductor substrate including a semiconductor material. The semiconductor material constituting the substrate 100 may include silicon (Si) or germanium (Ge). The substrate 100 may be a substrate including silicon carbide (SiC). The substrate 100 may be a substrate including a compound semiconductor material, such as gallium arsenide (GaAs), indium arsenide (InAs), or indium phosphide (InP). The substrate 100 may have a silicon-on-insulator (SOX) structure. Although not shown, the substrate 100 may include a structure doped with impurities or a well structure doped with impurities.

The substrate 100 may have a first surface 101 and a second surface 102, the second surface being opposite to the first surface 101. The first surface 101 of the substrate 100 may be a front side, and the second surface 102 may be a back side. The substrate 100 may have a shape of a wafer. Through vias may be formed in the substrate 100 through various types of processes. The through vias may be formed by using a through silicon via (TSV) process.

The process steps of forming the through vias in the substrate 100 may be performed after a front end of line (FEOL) process is performed on the first surface 101 of the substrate 100. The FEOL process may be a process of forming an active layer in the substrate 100 using oxidation, diffusion, ion implantation, or the like, The active layer may include a transistor or a capacitor constituting an integrated circuit.

The process steps of forming the through vias in the substrate 100 may be performed before the FEOL process, and the FEOL process may be performed on a structure in which the through vias are formed. Alternatively, after performing the FEOL process and a back end of line (BEOL) process on the first surface 101 of the substrate 100, the process steps of forming the through vias in the substrate 100 may be performed. The BEOL process play be a process of forming a wiring structure on the active layer.

After performing the FEOL process and the BEOL process on the first surface 101 of the substrate 100, the process steps of forming the through vias extending from the first surface 101 of the substrate 100 may be performed. Alternatively, after performing the FEOL process and the BEOL process on the first surface 101 of the substrate 100, the process steps of forming the through vias extending from the second surface 102 of the substrate 100 may be performed.

Integrated circuit components 105 may be formed on the first surface 101 of the substrate 100. The integrated circuit components 105 may constitute an integrated circuit integrated on the substrate 100. Each of the integrated circuit components 105 may include a transistor, a capacitor, a diode, or the like. The integrated circuit may include a memory device.

The dielectric layer 200 may be formed as an insulating layer that covers the integrated circuit components 105. The dielectric layer 200 may be an interlayer insulating layer formed in the FEOL process. The dielectric layer 200 may include a plurality of dielectric layers 210 and 220. Each of the dielectric layers 210 and 220 may include silicon oxide (SiO₂), silicon nitride (Si₃N₄), or silicon oxynitride (SiON).

The first dielectric layer 210 may include silicon oxide. The first dielectric layer 210 may include tetra-ethyl-Ortho-silicate (TEOS), high density plasma oxide (HDP oxide), borophosphosilicate glass (BPSG), flowable chemical vapor deposition oxide (FCVD oxide), or a low dielectric constant material having a low dielectric constant K of approximately 2.0 to 2.6. The low dielectric constant material may include silicon oxycarbide (SiOC) or SiCOH. The second dielectric layer 220 may include silicon nitride.

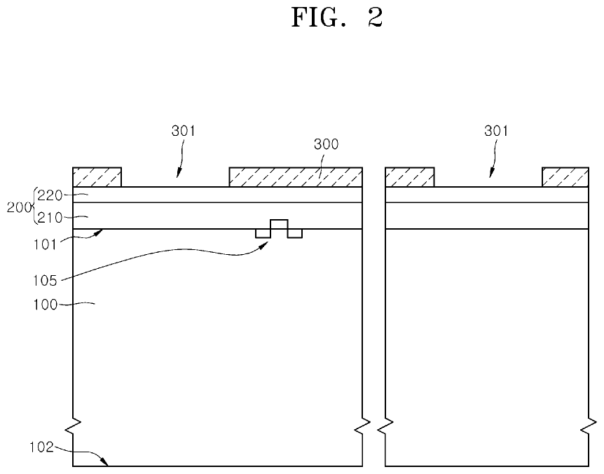

Referring to FIG. 2, an etch mask 300 may be formed over the substrate 100. The etch mask 300 may include a photoresist pattern. The photoresist pattern may be formed by performing a photo-lithography process on the dielectric layer 200. Specifically, a photoresist film may be formed on the dielectric layer 200, and the photoresist film may be exposed and developed to form the photoresist pattern. The etch mask 300 may further include a hard mask patterned by using the photoresist pattern. The hard mask may include a dielectric material other than the photoresist material. The hard mask may include a dielectric material, such as silicon oxide, silicon nitride, or amorphous carbon. The etch mask 300 may be formed on the dielectric layer 200, but in some cases, other material layers may be further interposed between the dielectric layer 200 and the etch mask 300.

The etch mask 300 may be a pattern that provides first openings 301 exposing some portions of an underlaying layer. The first openings 301 of the etch mask 300 may be located at positions where the through vias are to be formed. The first openings 301 may have substantially the same shape and size as each other. The first openings 301 may have substantially the same width as each other. The first openings 301 may have circular hole shapes having substantially the same diameter as each other.

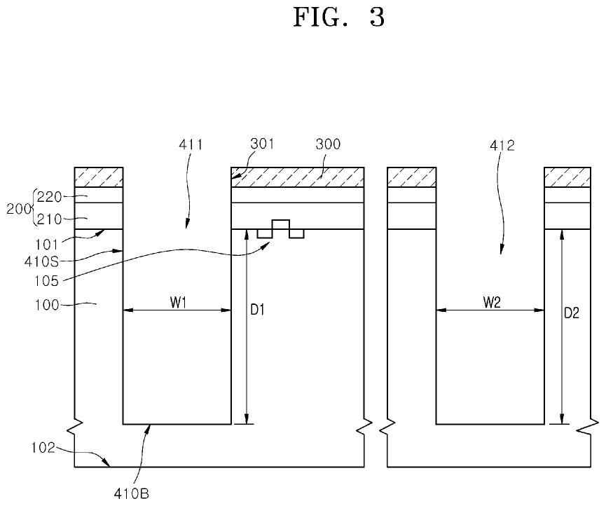

Referring to FIG. 3, first and second via holes 411 and 412 may be formed in the substrate 100. The portions of the dielectric layer 200 exposed by the first openings 301 of the etch mask 300 may be selectively etched and removed. As the portions of the dielectric layer 200 are removed, portions of the substrate 100 may be exposed and may be etched and removed. Each of etching processes for the exposed portions of the dielectric layer 200 and for the exposed portions of the substrate 100 may be performed by using a dry etch process or an anisotropic etch process. As the portions of the substrate 100 that overlap with the first openings 301 of the etch mask 300 are selectively removed, via holes including the first and second via holes 411 and 412 may be formed in the substrate 100.

The first via hole 411 and the second via hole 412 may be located at different regions of the substrate 100. The first and second via holes 411 and 412 may be formed by selectively removing the portions of the substrate 100 exposed by the first openings 301 of the etch mask 300. Accordingly, as the first openings 301 of the etch mask 300 expand or extend into the substrate 100, the first and second via holes 411 and 412 may be formed. Because the first openings 301 of the etch mask 300 have substantially the same width as each other, the first and second via holes 411 and 412 may be formed to have substantially the same width as each other. A first width W1 of the first via hole 411 may be substantially the same as a second width W2 of the second via hole 412. Because the first openings 301 of the etch mask 300 have substantially the same width as each other, the first and second via holes 411 and 412 may be formed to have substantially the same depth as each other. A first depth D1 of the first via hole 411 may be substantially the same as a second depth D2 of the second via hole 412.

The depths D1 and D2 of the first and second via holes 411 and 412 may indicate distances from the first surface 101 of the substrate 100 to bottom surfaces 410B of the first and second via holes 411 and 412, respectively. The widths W1 and W2 of the first and second via holes 411 and 412 may indicate distances between facing sidewall surfaces 410S of the first and second via holes 411 and 412, respectively. When each of the first and second via holes 411 and 412 is formed in a circular cylindrical shape, the widths W1 and W2 of the first and second via holes 411 and 412 may indicate the diameters of the circular shapes.

Because the first openings 301 of the etch mask 300 have substantially the same width as each other, the first via hole 411 and the second via hole 412 may be formed under substantially the same etch loading effect. Accordingly, the first via hole 411 and the second via hole 412 may have substantially the same widths W1 and W2, and may have substantially the same depths D1 and D2, respectively.

After the first via hole 411 and the second via hole 412 are formed in the substrate 100, the etch mask 300 may be removed.

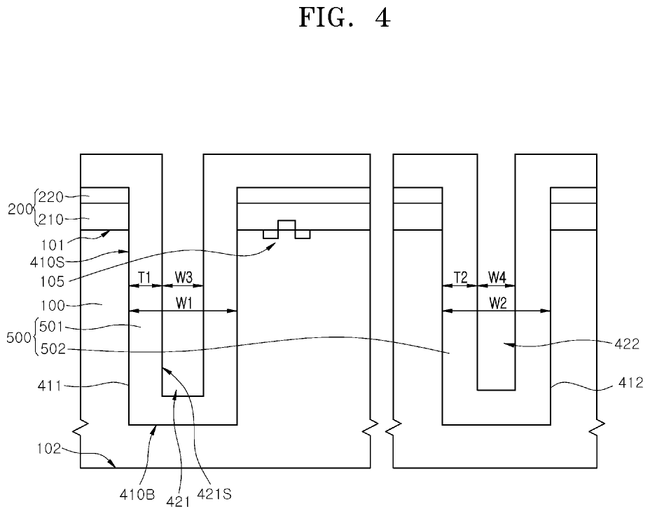

Referring to FIG. 4, an insulating layer 500 may be formed over the substrate 100 to extend along the shapes of the first and second via holes 411 and 412. The insulating layer 500 may be formed to have a linear shape that covers the dielectric layer 200 on the substrate 100 and extends into the first and second via holes 411 and 412. The insulating layer 500 may cover the dielectric layer 200 and may extend to cover the sidewall surfaces 410S and bottom surfaces 410B of the first and second via holes 411 and 412.

The insulating layer 500 may include an insulating layer first portion 501 and an insulating layer second portion 502. The insulating layer first portion 501 may be formed to provide a third via hole 421 in the first via hole 411 formed in the substrate 100. The insulating layer second portion 502 may be formed to provide a fourth via hole 422 in the second via hole 412 formed in the substrate 100. The insulating layer 500 may be formed such that the insulating layer first portion 501 covers the sidewall surface 410S of the first via hole 411 and the insulating layer second portion 502 covers the sidewall surface 4105 of the second via hole 412.

The insulating layer 500 may be deposited over the substrate 100 to conformally extend along a shape of a resultant structure in which the first and second via holes 411 and 412 are formed in the substrate 100. Accordingly, the insulating layer 500 may he formed such that the insulating layer first portion 501 has a first thickness T1 substantially the same as a second thickness T2 of the insulating layer second portion 502. The first thickness T1 of the insulating layer first portion 501 may indicate a distance from the sidewall surface 410S of the first via hole 411 to a sidewall surface 421S of the third via hole 421. The second thickness T2 of the insulating layer second portion 502 may indicate a distance from the sidewall surface 410S of the second via hole 412 to a sidewall surface of the fourth via hole 422.

Because the widths W1 and W2 of the first and second via holes 411 and 412 are substantially the same as each other and the first thickness T1 of the insulating layer first portion 501 is substantially the same as the second thickness T2 of the insulating layer second portion 502, a third width W3 of the third via hole 421 may be the same as a fourth width W4 of the fourth via hole 422.

The insulating layer 500 may be formed as a buffer layer that electrically isolates a silicon material of the substrate 100 and a metal material of the through vias and relieves stress. The insulating layer 500 may include silicon oxide. The insulating layer 500 may include tetraethyl orthosilicate (TEOS), high-density plasma (HDP) oxide, borophosphosilicate glass (BPSG), flowable chemical vapor deposition (FCVD) oxide, or a low-k material.

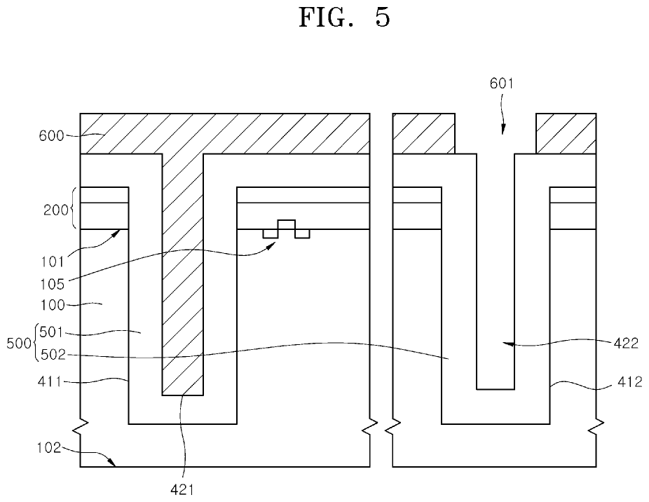

Referring to FIG. 5, a shielding pattern 600 that opens or leaves exposed a region including the fourth via hole 422 may be formed on the insulating layer 500. The shielding pattern 600 may be formed to cover or fill the third via hole 421. The shielding pattern 600 may be formed as a pattern that includes a second opening 601 selectively opening the fourth via hole 422 or a region including the fourth via hole 422. The second opening 601 of the shielding pattern 600 may be located to overlap with the fourth via hole 422. The shielding pattern 600 may be formed as a pattern that covers and shields the insulating layer first portion 501 and opens or leaves exposed the insulating layer second portion 502 through the second opening 601.

The shielding pattern 600 may include a photoresist pattern formed by performing a photo-lithography process on the insulating layer 500. Specifically, a photoresist film may be formed on the insulating layer 500 to fill the third via hole 421 and may be exposed and developed to form the photoresist pattern that opens the fourth via hole 422 or the region including the fourth via hole 422. The shielding pattern 600 may further include a dielectric material layer pattern formed by using the photoresist pattern. The dielectric material layer pattern may include a dielectric material other than the photoresist material. The dielectric material layer pattern may include a dielectric material, such as silicon oxide or amorphous carbon. The shielding pattern 600 may be formed on the insulating layer 500, but in some cases, other material layers may be further interposed between the insulating layer 500 and the shielding pattern 600.

Referring to FIG, 6, the fourth width W4 of the fourth via hole 422 may be selectively increased while maintaining the third width W3 of the third via hole 421. The fourth width W4 of the fourth via hole 422 may be increased to a fifth width W5 by reducing the second thickness T2 of the insulating layer second portion 502 to a third thickness T3. A portion of the insulating layer second portion 502 exposed by the second opening 601 of the shielding pattern 600 may be recessed, so that the insulating layer second portion 502 may be converted into a recessed insulating layer second portion 502-1 having a thickness reduced to the third thickness T3. An etch process may be performed on the insulating layer second portion 502 exposed by the shielding pattern 600, so that an expanded fourth via hole 422-1 may be formed to have the fifth width W5 that is wider than the third width W3 of the third via hole 421. The etch process for recessing the portion of the insulating layer second portion 502 may be performed by using an isotropic etch process. The etch process may be performed including a dry etch process or a wet etch process.

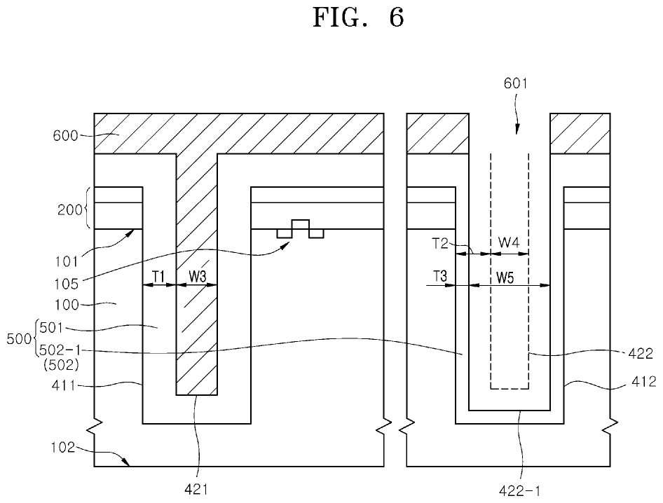

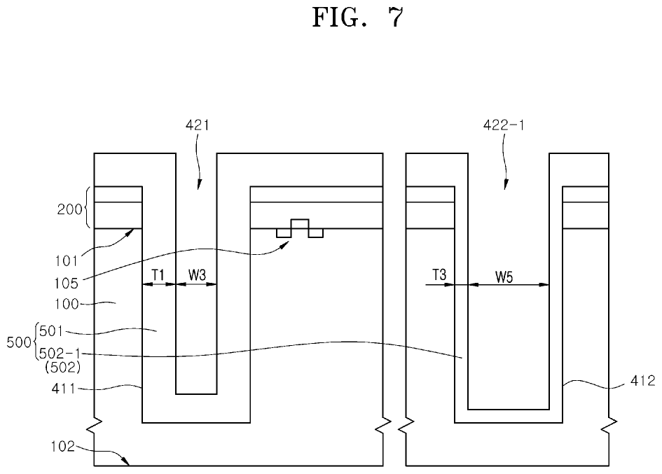

Referring to FIGS. 6 and 7, the shielding pattern 600 may be removed to expose the third via hole 421 and the expanded fourth via hole 422-1. The expanded fourth via hole 422-1 may have the fifth width W5 that is wider than the third width W3 of the third via hole 421. The expanded fourth via hole 422-1 of fifth width W5 may be expanded to be wider than the fourth via hole 422 of the fourth width W4 by twice the thickness reduction of the recessed insulating layer second portion 502-1. Because the third width W3 of the third via hole 421 has substantially the same size as the fourth width W4 of the fourth via hole 422 before being expanded, the fifth width W5 of the expanded fourth via hole 422-1 may be wider than the third width W3 of the third via hole 421. Through these processes, the third via hole 421 and the expanded fourth via hole 422-1 having different widths W3 and W5, respectively, may be formed together in the substrate 100.

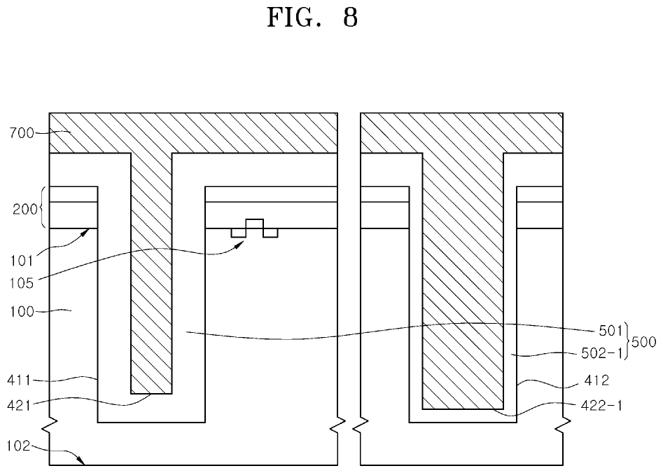

Referring to FIG. 8, a conductive layer 700 may be formed over the substrate 100. The conductive layer 700 may extend to fill the third via hole 421 and the expanded fourth via hole 422-1 that are formed in the substrate 100. The conductive layer 700 may be formed as a metal layer including copper (Cu). A copper (Cu) layer may be formed by using a plating process. A plating seed layer for plating copper (Cu) may be formed over the substrate 100 before forming the copper (Cu) layer. In order to suppress or prevent diffusion of copper (Cu) ions included in the conductive layer 700 into the substrate 100, a diffusion barrier layer may be formed at an interface between the copper (Cu) layer and the insulating layer 500. The diffusion barrier layer may include a tantalum (Ta) layer or a tantalum nitride (TaN) layer. The diffusion barrier layer may include a double layer of a tantalum (Ta) layer and a tantalum nitride (Tali) layer. The conductive layer 700 may include a double layer of a diffusion barrier layer and a copper (Cu) layer.

Referring to FIG, 9, a first through via 701 located in the third via hole 421 and a second through via 702 located in the expanded fourth via hole 422-1 may be formed. The first through via 701 and the second through via 702 may be separated from the conductive layer (700 of FIG. 8). The conductive layer 700 may be planarized to separate the first through via 701 as a portion of the conductive layer 700 filling the third via hole 421. The conductive layer 700 may be planarized to separate the second through via 702 as another portion of the conductive layer 700 filling the expanded fourth via hole 422-1. The conductive layer 700 may be separated into the first through via 701 and the second through via 702 by a planarization process, such as chemical mechanical polishing (CMP).

Each of the first and second through vias 701 and 702 may be formed in a form of a through-silicon via (TSV). The first through via 701 and the second through via 702 may have different widths W3 and W5, respectively, depending on the different thicknesses T1 and T3 of the insulating layer first portion 501 and the recessed insulating layer second portion 502-1, respectively. The first through via 701 may have a width that is substantially the same as the third width W3 of the third via hole 421, and the second through via 702 may have a width that is substantially the same as the fifth width W5 of the expanded fourth via hole 422-1. Because the fifth width W5 of the expanded fourth via hole 422-1 is wider than the third width W3 of the third via hole 421 by twice the thickness reduction of the recessed insulating layer second portion 502-1, the second through via 702 may have the fifth width W5 that is wider than the width of the first through via 701 by twice the thickness reduction of the recessed insulating layer second portion 502-1.

The second through via 702 may be induced to have the fifth width W5 different from the third width W3 of the first through via 701 while the first via hole 411 and the second via hole 412 are formed to have widths W1 and W2 of substantially the same size. The insulating layer second portion 502-1 may be recessed such that the third thickness T3 of the recessed insulating layer second portion 502-1 is thinner than the first thickness T1 of the insulating layer first portion 501. Accordingly, the second through via 702 may have the fifth width W5 that is wider than the third width W3 of the first though via 701.

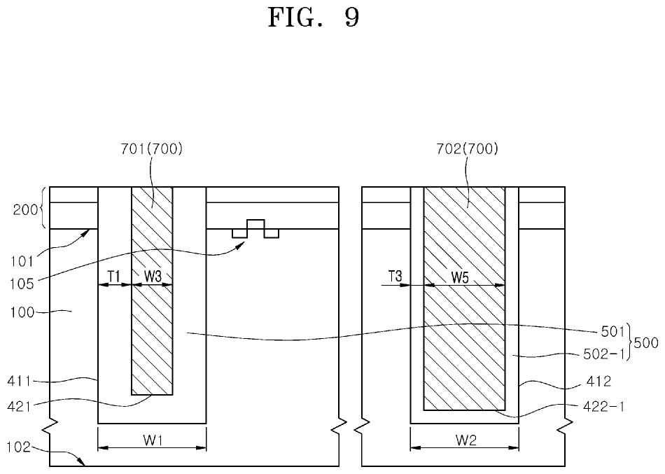

Referring to FIG. 9, together with FIG, 2, if the first openings 301 of the etch mask 300 have different widths from each other, the first and second via holes may be affected by different etch loading effects. If the first and second via holes are formed under the different etch loading effects, it may be difficult to control the etching process for forming the first and second via holes. If the first and second via holes are formed under the different loading effects, the first and second via holes may have different widths and may be formed with different depths. If the difference between the depths of the first and second via holes increases, it may be difficult to fill the first and second via holes with a conductive layer. In addition, the length difference between the through vias filling the first and second via holes becomes large, and thus, additional processes for reducing the length difference may be required.

In the embodiment of the present disclosure, the first openings 301 of the etch mask 300 may be formed to have substantially the same width, and the first and second via holes 411 and 412 may be formed to have substantially the same shape as each other. Accordingly, differences in etching loading effects applied to the first and second via holes 411 and 412 may be reduced. Accordingly, the length difference between the first through via 701 and the second through via 702 may be reduced.

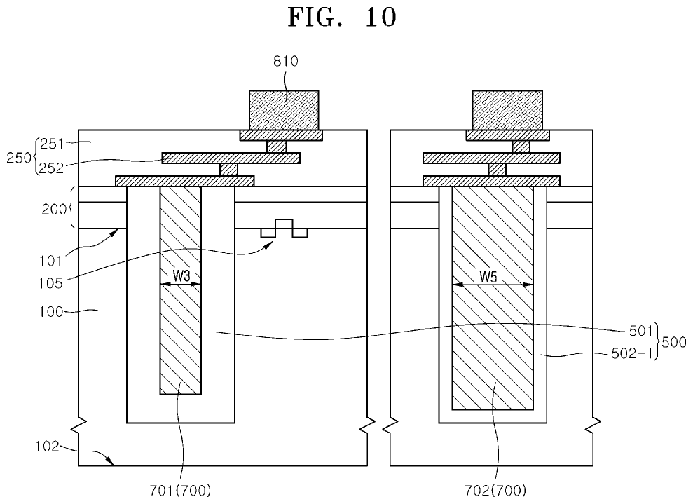

Referring to FIG. 10, first connecting portions 810 may be formed to be electrically connected to the first and second through vias 701 and 702. Specifically, after the first and second through vias 701 and 702 are formed, a wiring structure layer 250 may be formed over the first surface 101 of the substrate 100. The wiring structure layer 250 may be formed through a BEOL process. The wiring structure layer 250 may be formed on the underlaying dielectric layer 200. The wiring structure layer 250 may include a third dielectric layer 251 and wiring layers 252 formed in the third dielectric layer 251. The wiring layers 252 may include a multi-metallization structure. The wiring layers 252 may include metal layers, such as aluminum (Al) layers, The third dielectric layer 251 may be formed as an intermetallic insulating layer.

The first connecting portions 810 may be formed to be electrically connected to the wiring layers 252. The first connecting portions 810 may be electrically connected to the first and second through vias 701 and 702 through the wiring layers 252. Each of the first connecting portions 810 may be formed in a shape of a conductive bump. The conductive bump may be formed of a conductive material including copper (Cu). Although the first connecting portions 810 are described as conductive bumps, the first connecting portions 810 are not limited to being conductive bumps. Each of the first connecting portions 810 may be formed in a form of a conductive pad, for example.

The wiring layers 252 may be formed to electrically connect the first connecting portions 810 to the first and second vias 701 and 702, and may also be formed to electrically connect the first and second through vias 701 and 702 to the integrated circuit components 105 formed on the first surface 101 of the substrate 100. The first through via 701 having the third width W3 that is narrower than the fifth width W5 of the second through via 702 may provide a path for transferring a data signal to the integrated circuit components 105. The second through via 702 having the fifth width W5 that is wider than the third width W3 of the first through via 701 may provide a path for providing power to the integrated circuit components 105. Thus, for example, a power path has a greater conductor cross section than a data path.

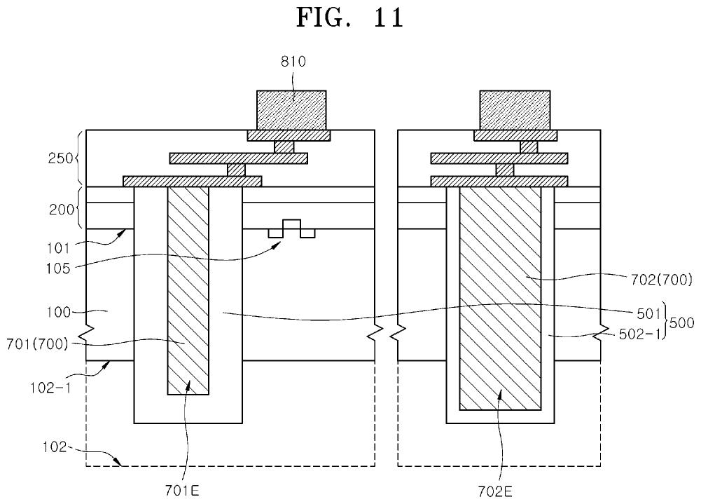

Referring to FIG. 11, a portion of the substrate 100 may be recessed from the second surface 102 of the substrate 100. A process of recessing the portion of the substrate 100 may be performed such that an end portion 701E of the first through via 701 and an end portion 702E of the second through via 702 protrude from a recessed second surface 102-1. By recessing and removing the portion of the substrate 100 from the second surface 102 of the substrate 100, the thickness of the substrate 100 may be reduced. Through the thinning process for the substrate 100, the first through via 701 and the second through via 702 may substantially penetrate the substrate 100. The first and second through vias 701 and 702 may extend from the first surface 101 of the substrate 100 to the recessed second surface 102-1, and may substantially penetrate the substrate 100.

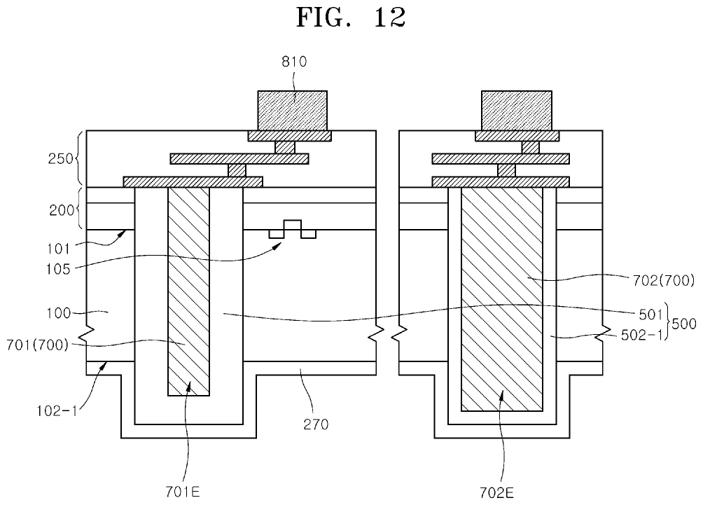

Referring to FIG. 12, a fourth dielectric layer 270 may be formed to cover the recessed second surface 102-1 of the substrate 100. The fourth dielectric layer 270 may include silicon oxide or silicon nitride. The fourth dielectric layer 270 may include a double layer of silicon oxide layer and a silicon nitride layer. The fourth dielectric layer 270 may be formed as a layer that protects the recessed second surface 102-1 of the substrate 100.

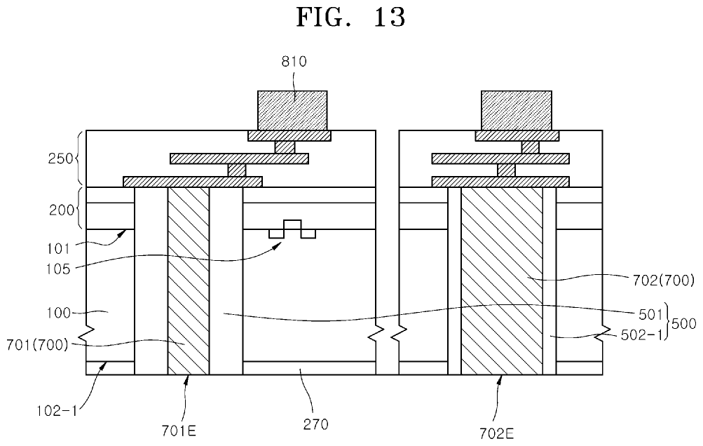

Referring to FIG. 13, the end portions 701E and 702E of the first and second through vias 701 and 702 may be exposed to the outside of the fourth dielectric layer 270. Specifically, by performing a planarization process on the fourth dielectric layer 270, lower surfaces of the end portions 701E and 702E of the first and second through vias 701 and 702 may be exposed to the outside of the fourth dielectric layer 270.

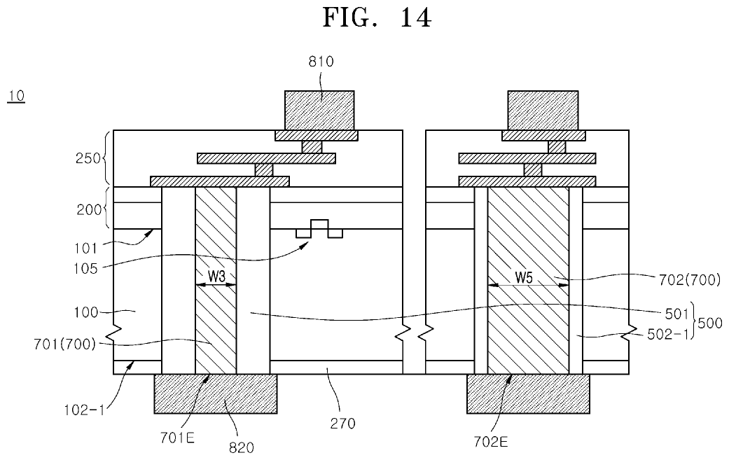

Referring to FIG. 14, second connecting portions 820 may be formed to be electrically connected to the end portion 701E of the first through via 701 and the end portion 702E of the second through via 702. Each of the second connecting portions 820 may be formed in a form of a conductive bump. The conductive bump may be formed of a conductive material including copper (Cu). Although each of the second connecting portions 820 is described as a conductive bump, the form of the second connecting portion 820 is not limited to being a conductive bump. Each of the second connecting portions 820 may be formed in a form of a conductive pad, for example.

Through the above-described process, the semiconductor device 10 according to an embodiment may be implemented. The semiconductor device 10 may include the first and second through vias 701 and 702 having different widths W3 and W5, respectively.

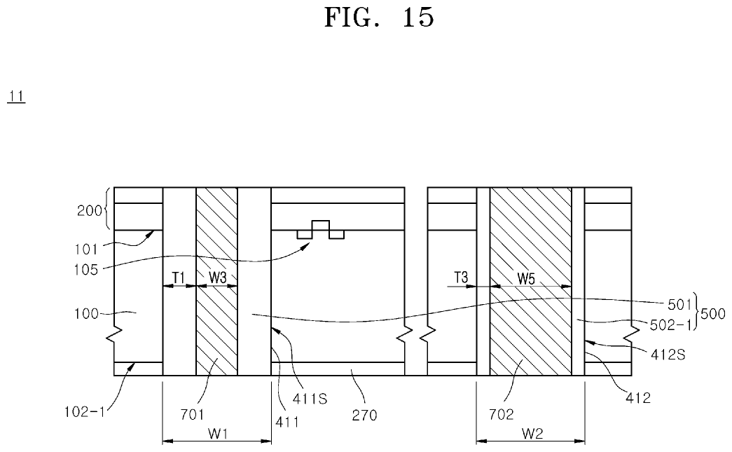

FIG. 15 is a schematic diagram illustrating a semiconductor device 11 according to another embodiment of the present disclosure. Referring to FIG. 15, the semiconductor device 11 according to another embodiment may include a first through via 701 and a second through via 702 that substantially penetrate a substrate 100. The substrate 100 may include a first via hole 411 and a second via hole 412. The first and second via holes 411 and 412 may be formed as through holes extending from a first surface 101 of the substrate 100 to a second surface 102-1 on the opposite side.

The first through via 701 and the second through via 702 may extend from the first surface 101 of the substrate 100 to the second surface 102-1 on the opposite side. The first through via 701 may be formed in the first via hole 411, and the second through via 702 may be formed in the second via hole 412. An insulating layer first portion 501 may be formed at an interface between a sidewall surface 411S of the first via hole 411 and the first through via 701. An insulating layer second portion 502-1 may be formed at an interface between a sidewall surface 412S of the second via hole 412 and the second through via 702.

A first width W1 of the first via hole 411 may be substantially the same as a second width W2 of the second via hole 412. A third thickness T3 of the insulating layer second portion 502-1 may be thinner than a first thickness T1 of the insulating layer first portion 501. A fifth width W5 of the second through via 702 may be wider than a third width W3 of the first through via 701. The second through via 702 may have a wider width than the first through via 701 by twice the thickness difference of the insulating layer second portion 502-1 and the insulating layer first portion 501.

First and second connecting portions 810 and 820 as illustrated in FIG. 14 may be electrically connected to the first and second through vias 701 and 702 of the semiconductor device 11, respectively. Alternatively, through vias of other semiconductor devices may be directly coupled to the first and second through vias 701 and 702 of the semiconductor device 11. In a case where another semiconductor device is stacked on the semiconductor device 11 by a direct bonding method, such as hybrid bonding or wafer bonding, the first and second connecting portions 810 and 820 may be omitted.

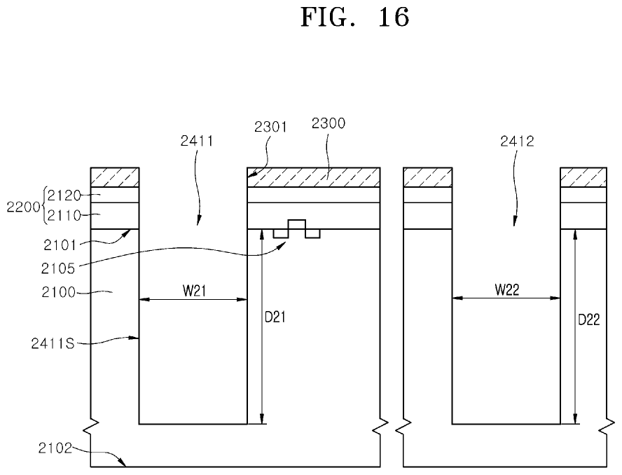

FIGS. 16 to 27 are schematic diagrams illustrating a semiconductor device according to another embodiment of the present disclosure and a method of manufacturing the same.

Referring to FIG. 16, first and second via holes 2411 and 2412 may be formed in a substrate 2100. The substrate 2100 may be a semiconductor substrate including a semiconductor material. The substrate 2100 may have a first surface 2101 and a second surface 2102 that are opposite to each other. Process steps of forming through vias in the substrate 2100 may be performed after performing the FEOL process on the first surface 2101 of the substrate 2100. The process steps of forming the through vias in the substrate 2100 may be performed before the FEOL process, and the FEOL process may be performed on a structure in which the through vias are formed. Alternatively, after performing the FEOL process and the BEOL process on the first surface 2101 of the substrate 2100, the process steps of forming the through vias in the substrate 2100 may be performed. After the FEOL process and the BEOL process are performed on the first surface 2101 of the substrate 2100, the process steps for forming the through vias extending from the first surface 2101 of the substrate 2100 may be performed. Alternatively, after the FEOL process and the BEOL process are performed on the first surface 2101 of the substrate 2100, the process steps for forming the through vias extending from the second surface 2102 of the substrate 2100 may be performed.

Integrated circuit components 2105 may be formed on the first surface 2101 of the substrate 2100. The integrated circuit components 2105 may constitute an integrated circuit (IC) integrated on the substrate 2100. A dielectric layer 2200 may be formed on the first surface 2101 of the substrate 2100. The dielectric layer 2200 may be formed as an insulating layer that covers the integrated circuit components 2105. The dielectric layer 2200 may be an interlayer insulating layer formed in the FEOL process. The dielectric layer 2200 may include a plurality of dielectric layers 2210 and 2220. A first dielectric layer 2210 may include silicon oxide. A second dielectric layer 2220 may include silicon nitride.

An etch mask 2300 may be formed over the substrate 2100. The etch mask 2300 may include a photoresist pattern. The photoresist pattern may be formed by forming a photoresist film on the dielectric layer 2200 and exposing and developing the photoresist film. The etch mask 2300 may further include a hard mask patterned by using the photoresist pattern. The hard mask may include a dielectric material, such as silicon oxide, silicon nitride, or amorphous carbon. The etch mask 2300 may be formed on the dielectric layer 2200, but in some cases, other material layers may be further interposed between the dielectric layer 2200 and the etch mask 2300.

The etch mask 2300 may be a pattern that provides first openings 2301 exposing some portions of an underlaying layer. The first openings 2301 of the etch mask 2300 may be located at positions where through vias are to be formed. The first openings 2301 may have substantially the same shape and size as each other. The first openings 2301 may have substantially the same width as each other, The first openings 2301 may have shapes of circular holes, the circular holes having substantially the same diameter as each other.

The portions of the dielectric layer 2200 exposed by the first openings 2301 of the etch mask 2300 may be selectively etched and removed. The portions of the substrate 2100, that is exposed as the portions of the dielectric layer 2200 are removed, may be etched and removed. As the portions of the substrate 2100, that overlap with the first openings 2301 of the etch mask 2300, are selectively removed, via holes including first and second via holes 2411 and 2412 may be for led in the substrate 2100.

The first via hole 2411 and the second via hole 2412 may be respectively located in different regions of the substrate 2100. As the first openings 2301 of the etch mask 2300 extend or expand into the substrate 2100, the first and second via holes 2411 and 2412 may be formed. Because the first openings 2301 of the etch mask 2300 have substantially the same width as each other, the first via hole 2411 and the second via hole 2412 may be formed to have substantially the same width as each other. A first width W21 of the first via hole 2411 may be the same as a second width W22 of the second via hole 2412. Because the first openings 2301 of the etch mask 2300 have substantially the same width as each other, the first via hole 2411 and the second via hole 2412 may be formed to have substantially the same depth as each other. A first depth D21 of the first via hole 2411 may be substantially the same as a second depth D22 of the second via hole 2412.

Because the first openings 2301 of the etch mask 2300 have substantially the same width as each other, the first via hole 2411 and the second via hole 2412 may be formed under substantially the same etch loading effect. Accordingly, the first via hole 2411 and the second via hole 2412 may have substantially the same widths W21 and W22 and substantially the same depths D21 and D22, respectively.

After the first via hole 2411 and the second via hole 2412 are formed in the substrate 2100, the etch mask 2300 nay be removed,

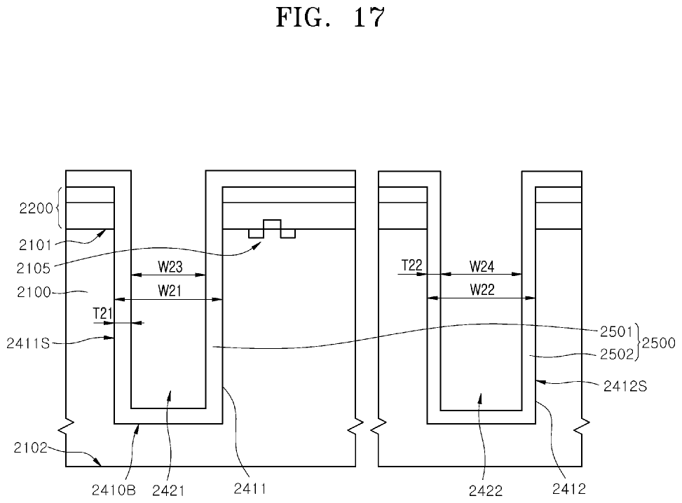

Referring to FIG. 17, a first insulating layer 2500 extending along the shape of each of the first and second via holes 2411 and 2412 may be formed over the substrate 2100. The first insulating layer 2500 may be formed to have a linear shape that covers the dielectric layer 2200 on the substrate 2100 and extends inside the first and second via holes 2411 and 2412. The first insulating layer 2500 may cover the dielectric layer 2200, and may extend to cover the sidewall surfaces 24115 and 24125 and the bottom surfaces 2410B of the first and second via holes 2411 and 2412.

The first insulating layer 2500 may include a first insulating sayer first portion 2501 and a first insulating sayer second portion 2502. The first insulating layer first portion 2501 may be formed to provide a third via hose 2421 in the first via hole 2411 formed in the substrate 2100. The first insulating layer second portion 2502 may be formed to provide a fourth via hole 2422 in the second via hole 2412 formed in the substrate 2100. The first insulating layer 2500 may be formed such that the first insulating layer first portion 2501 covers the sidewall surface 24115 of the first via hole 2411 and the first insulating layer second portion 2502 covers the sidewall surface 24125 of the second via hole 2412.

The first insulating layer 2500 may be deposited over the substrate 2100 to conformally extend along a shape of a resultant structure in which the first and second via holes 2411 and 2412 are formed in the substrate 2100. Accordingly, the first insulating layer 2500 may be formed such that a first thickness T21 of the first insulating layer first portion 2501 is substantially the same as a second thickness T22 of the first insulating layer second portion 2502, Because the widths W21 and W22 of the first and second via holes 2411 and 2412 are substantially the same as each other and the first thickness T21 of the first insulating layer first portion 2501 is substantially the same as the second thickness T22 of the first insulating layer second portion 2502, a third width W23 of the third via hole 2421 may be substantially the same as a fourth width W24 of the fourth via hole 2422.

The first insulating layer 2500 may be formed as a buffer layer that electrically isolates a silicon material of the substrate 2100 from a metal material of the through via and relieves stress. The first insulating layer 2500 may include silicon oxide. The first insulating layer 2500 may include TEOS, HDP oxide, BPSG, ECVD oxide, or a low-k material.

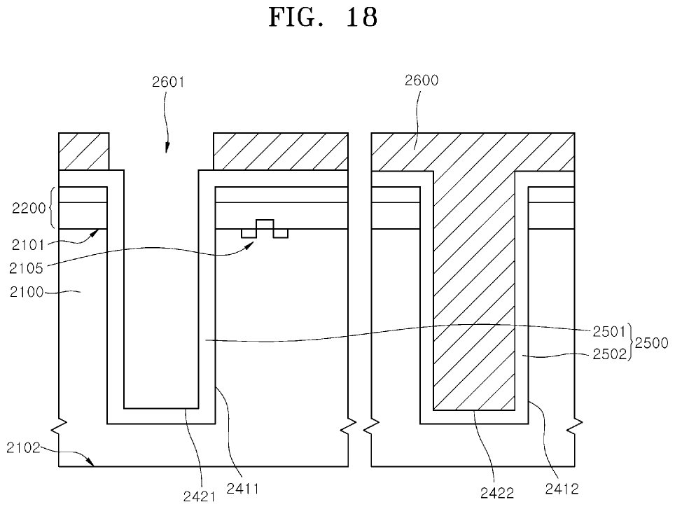

Referring to FIG. 18, a shielding pattern 2600 that opens or leaves exposed a region including the third via hole 2421 may be formed on the first insulating layer 2500. The shielding pattern 2600 may be formed to cover or fill the fourth via hole 2422. The shielding pattern 2600 may be formed as a pattern that includes a second opening 2601, the second opening 2601 selectively opening the third via hole 2421 or a region including the third via hole 2421. The second opening 2601 of the shielding pattern 2600 may be positioned to overlap with the third via hole 2421. The shielding pattern 2600 may be formed as a pattern that covers and shields the first insulating layer second portion 2502 and opens or leaves exposed the first insulating layer first portion 2501 through the second opening 2601.

The shielding pattern 2600 may include a photoresist pattern formed by performing a photo-lithography process on the first insulating layer 2500. A photoresist film may be formed on the first insulating layer 2500 to fill the fourth via hole 2422 and may be exposed and developed to form the photoresist pattern that opens or leaves exposed the third via hole 2421 or a region including the third via hole 2421. The shielding pattern 2600 may further include a dielectric material layer pattern patterned by using the photoresist pattern. The dielectric material layer pattern may include a dielectric material other than the photoresist material. The dielectric material layer pattern may include a dielectric material, such as silicon oxide or amorphous carbon. The shielding pattern 2600 may be formed on the first insulating layer 2500, but in some cases, other material layers may be further interposed between the first insulating layer 2500 and the shielding pattern 2600. The shielding pattern 2600 may include the photoresist pattern, and may further include a dielectric material layer pattern covering the photoresist pattern.

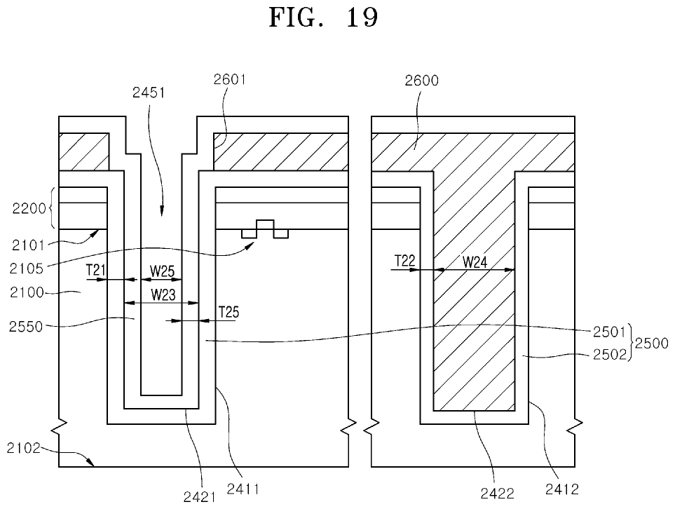

Referring to FIG. 19, a second insulating layer 2550 may be formed to overlap with the first insulating layer first portion 2501, The second insulating layer 2550 may be formed to provide a fifth via hole 2451 in the third via hole 2421. The second insulating layer 2550 extending along the shape of the third via hole 2421 may be formed to cover a portion of the first insulating layer first portion 2501. The second insulating layer 2550 may be formed to further extend to cover the shielding pattern 2600. The second insulating layer 2550 may be formed to have a linear shape that covers the first insulating layer first portion 2501 and extends to cover the shielding pattern 2600. The second insulating layer 2550 may be formed to extend along a shape of the third via hole 2421 and to provide the fifth via hole 2451 in the third via hole 2421. The first insulating layer first portion 2501 may be opened and exposed by the shielding pattern 2600, so that the second insulating layer 2550 may be directly deposited on the first insulating layer first portion 2501. Because the first insulating layer second portion 2502 and the fourth via hole 2422 are shielded by the shielding pattern 2600, the second insulating layer 2550 might not contact the first insulating layer second portion 2502 and might not extend inside the fourth via hole 2422.

The second insulating layer 2550 may extend to overlap with the first insulating layer first portion 2501. The second insulating layer 2550 may be formed on the first insulating layer first portion 2501 in a third thickness T25. Accordingly, a structure in which the first insulating layer first portion 2501 and the second insulating layer 2550 are overlapped may be formed between the sidewall surface 2411S of the first via hole 2411 and the fifth via hole 2451. A thick insulating layer structure having a thickness in which the first thickness T21 of the first insulating layer 2501 and the third thickness T25 of the second insulating layer 2550 overlap may be formed between the sidewall surface 2411S of the first via hole 2411 and the fifth via hole 2451.

The fifth via hole 2451 provided in the third via hole 2421 may have a fifth width W25 that is narrower than the third width W23 of the third via hole 2421. The fifth width W25 of the fifth via hole 2451 may be narrower than the third width W23 of the third via hole 2421 by twice the third thickness T25 of the second insulating layer 2550. Because the fourth width W24 of the fourth via hole 2422 is substantially the same as the third width W23 of the third via hole 2421, the fifth width W25 of the fifth via hole 2451 may be narrower than the fourth width W24 of the fourth via hole 2422 by twice the third thickness T25 of the second insulating layer 2550.

Each of the first insulating layer first portion 2501 and the second insulating layer 2550 may be formed as a buffer layer that electrically isolates a silicon material of the substrate 2100 and a metal material of the through vias and relieves stress. The second insulating layer 2550 may include a dielectric material, such as silicon oxide. Because the second insulating layer 2550 extends onto the shielding pattern 2600, when the shielding pattern 2600 includes a photoresist material, a process of forming the second insulating layer 2550 may be performed at a temperature lower than the decomposition temperature or glass transition temperature (Tg) of the photoresist material constituting the shielding pattern 2600. The second insulating layer 2550 may include silicon oxide that is formed at a temperature lower than the decomposition temperature or glass transition temperature (Tg) of the photoresist material.

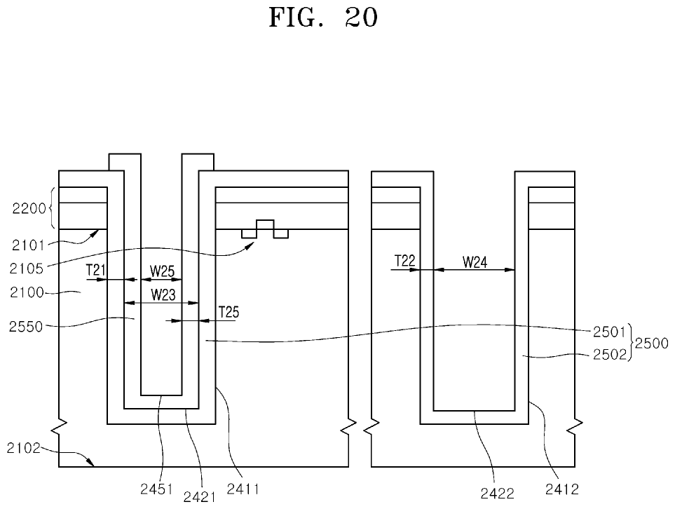

Referring to FIGS. 19 and 20, the shielding pattern 2600 may be removed to expose the fifth via hole 2451 and the fourth via hole 2422. When or before the shielding pattern 2600 is removed, the portion of the second insulating layer 2550 that overlaps with the shielding pattern 2600 may also be removed. Accordingly, most of the second insulating layer 2550 may be limited to be located in the fifth via hole 2451. The fifth via hole 2451 may have the fifth width W25 that is narrower than the fourth width W24 of the fourth via hole 2422. The fifth width W25 of the fifth via hole 2451 may he narrower than the fourth width W24 of the fourth via hole 2422 by twice the third thickness T25 of the second insulating layer 2550. Through these processes, the fifth via hole 2451 and the fourth via hole 2422 having different widths W25 and W24, respectively, may be formed together in the substrate 2100.

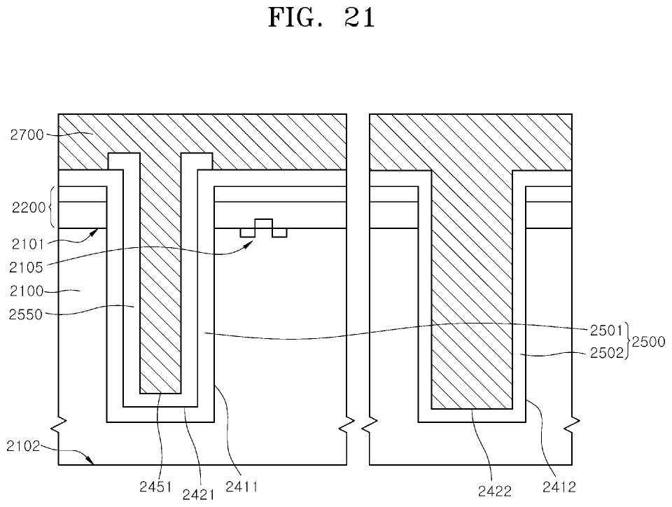

Referring to FIG. 21, a conductive layer 2700 may be formed over the substrate 2100. The conductive layer 2700 may extend to fill the fifth via hole 2451 and the fourth via hole 2422 formed in the substrate 2100. The conductive layer 2700 may be formed in a metal layer including copper (Cu). A copper (Cu) layer may be formed by a plating process. A plating seed layer for plating copper (Cu) may be formed over the substrate 2100 before plating the copper (Cu) layer. In order to suppress or prevent diffusion of copper (Cu) ions included in the conductive layer 2700 into the substrate 2100, diffusion barrier layers may be formed at an interface between the copper (Cu) layer and the first insulating layer second portion 2502 and at an interface between the copper (Cu) layer and the second insulating layer 2550. The diffusion barrier layer may include a tantalum (Ta) layer or a tantalum nitride (TiN) layer. The diffusion barrier layer may include a bilayer of a tantalum (Ta) layer and a tantalum nitride (TiN) layer. The conductive layer 2700 may include a double layer of a diffusion barrier layer and a copper (Cu) layer.

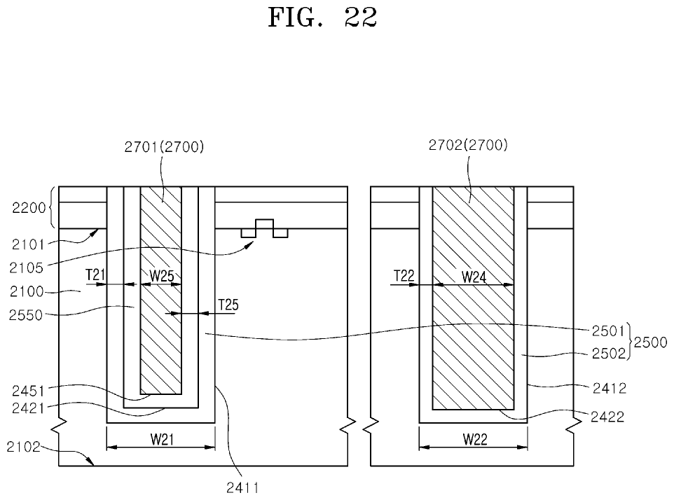

Referring to FIG. 22, a first through via 2701 may be formed in the fifth via hole 2451 and a second through via 2702 may be formed in the fourth via hole 2422. The first through via 2701 and the second through via 2702 may be separated from the conductive layer 2700. Specifically, the conductive layer 2700 may be planarized to separate the first through via 2701 as a portion of the conductive layer 2700 filling the fifth via hole 2451. The conductive layer 2700 may be planarized to separate the second through via 2702 as another portion of the conductive layer 2700 filling the fourth via hole 2422. The conductive layer 2700 may be separated into the first through via 2701 and the second through via 2702 by using a planarization process, such as chemical mechanical polishing (CMP).

Each of the first and second through vias 2701 and 2702 may be formed in a form of a through silicon via (TSV). The first through via 2701 and the second through via 2702 may have different widths W25 and W24, respectively, depending on a difference in thickness between the thickness T21+T25 of the overlapping portion of the first insulating layer first portion 2501 and the second insulating layer 2550 and the thickness T22 of the first insulating layer second portion 2502. The first through via 2701 may have the width substantially the same as the fifth width W25 of the fifth via hole 2451, and the second through via 2702 may have the width substantially the same as the fourth width W24 of the fourth via hole 2422. Because the fifth width W25 of the fifth via hole 2451 is narrower than the fourth width W24 of the fourth via hole 2422 by twice the third thickness T25 of the second insulating layer 2550, the first through via 2701 may have the narrower fifth width W25 than the second through via 2702 by twice the third thickness T25 of the second insulating layer 2550. The second through via 2702 may have the wider fifth width W25 than the first through via 2701 by twice the third thickness T25 of the second insulating layer 2550. As such, the second through via 2702 may have a wider width than the first through via 2701. The second through via 2702 may be induced to have the fourth width W24 different from the fifth width W25 of the first through via 2701 while the first via hole 2411 and the second via hole 2412 are formed to have widths W21 and W22 of substantially the same size.

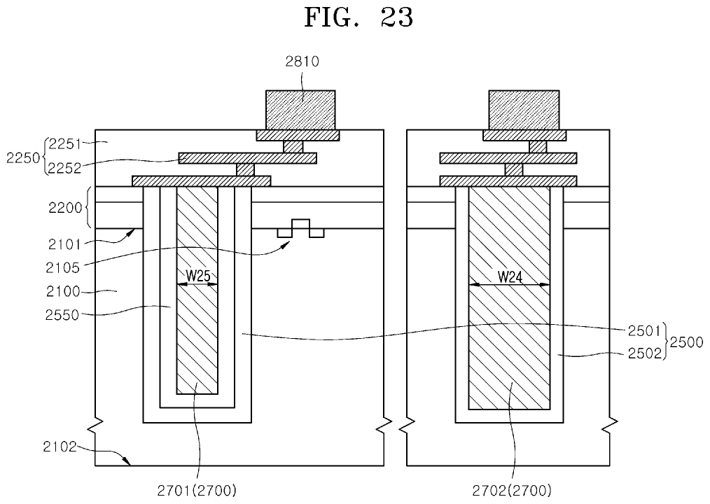

Referring to FIG. 23, first connecting portions 2810 may be formed to be electrically connected to the first through via 2701 and the second through via 2702. After the first and second through vias 2701 and 2702 are formed, wiring structure layers 2250 may be formed over the first surface 2101 of the substrate 2100. The wiring structure layers 2250 may be formed through the BEOL process. The wiring structure layers 2250 may be formed on the underlying dielectric layer 220. Each of the wiring structure layers 2250 may include a third dielectric layer 2251 and a wiring layers 2252 formed in the third dielectric layer 2251. Each of the wiring layers 2252 may include a multi-layered metal layer. Each of the wiring layers 2252 may include a metal layer, such as an aluminum (Al) layer. The third dielectric layer 2251 may be formed as an intermetallic insulating layer.

The first connecting portions 2810 may be formed to be electrically connected to the wiring layers 2252. The first connecting portions 2810 may be electrically connected to the first and second through vias 2701 and 2702 through the wiring layers 2252. Each of the first connecting portions 2810 may be formed in a shape of a conductive bump. The conductive bump may be formed of a conductive material including copper (Cu). Although the first connecting portions 2810 are described as conductive bumps, the first connecting portions 2810 are not limited to the shape of the conductive bumps. Each of the first connecting portions 2810 may be formed in a shape of a conductive pad, for example.

The wiring layers 2252 may be formed to electrically connect the first connecting portions 2810 to the first and second through vias 2701 and 2702, and may electrically connect the first and second through vias 2701 and 2702 to the integrated circuit components 2105 formed on the first surface 2101 of the substrate 2100. The first through via 2701 having the fifth width W25 that is narrower than the fourth width W24 of the second through via 2702 may provide a path for transmitting a data signal to the integrated circuit components 2105. The second through via 2702 having the fourth width W24 that is wider than the fifth width W25 of the first through via 2701 may provide a path for providing power to the integrated circuit components 2105. Thus, for example, a power path has a greater conductor cross section than a data path.

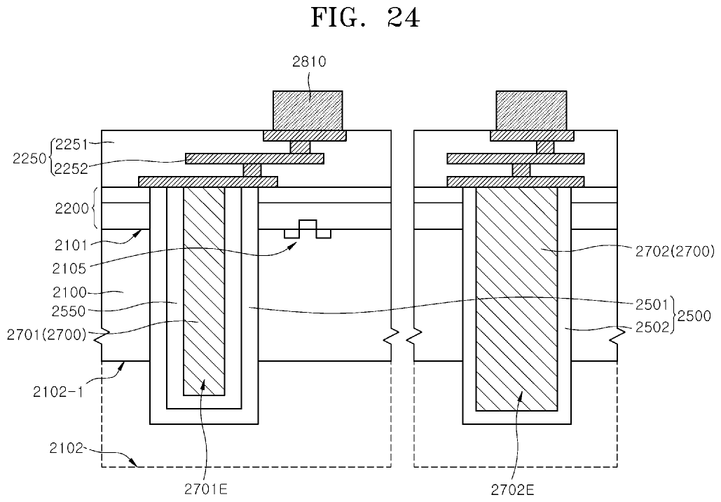

Referring to FIG. 24, a portion of the substrate 2100 may be recessed from the second surface 2102 of the substrate 2100. A recess process may be performed such that end portions 2701E and 2702E of the first and second through vias 2710 and 2702, respectively, protrude from a recessed second surface 2102-1. By recessing and removing the portion of the substrate 2100 from the second surface 2102 of the substrate 2100, the thickness of the substrate 2100 may be reduced. In addition, by the thinning process performing on the substrate 2100, the first and second through vias 2701 and 2702 may substantially penetrate the substrate 2100.

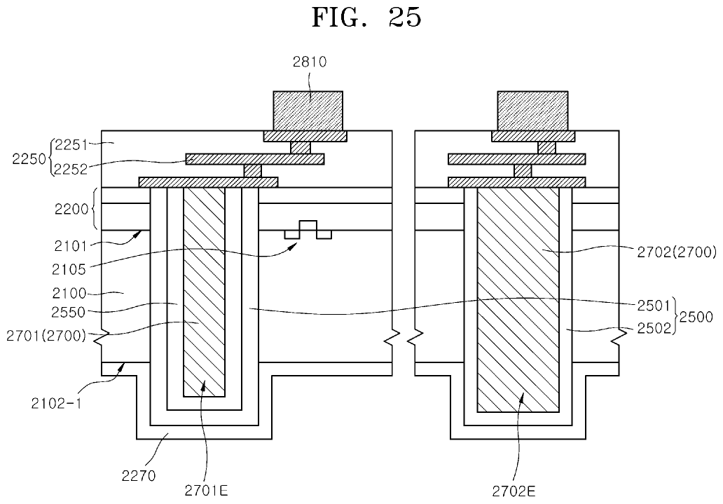

Referring to FIG. 25, a fourth dielectric layer 2270 may be formed to cover the recessed second surface 2102-1 of the substrate 2100. The fourth dielectric layer 2270 may include silicon oxide or silicon nitride. The fourth dielectric layer 2270 may include a bilayer of a silicon oxide layer and a silicon nitride layer. The fourth dielectric layer 2270 may be formed as a layer that protects the recessed second surface 2102-1 of the substrate 2100.

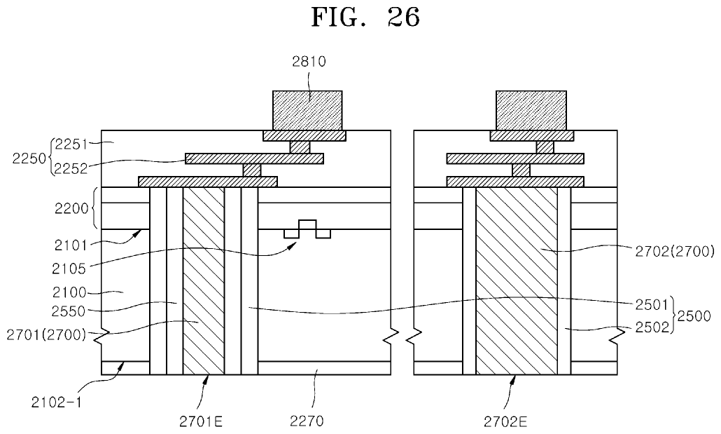

Referring to FIG. 26, the end portion 2701E of the first through via 2701 and the end portion 2702E of the second through via 2702 may be exposed to the outside of the fourth dielectric layer 2270. To this end, a planarization process may be performed on the fourth dielectric layer 2270 to expose lower surfaces of the end portions 2701E and 2702E of the first and second through vias 2701 and 2702, respectively, to the outside of the fourth dielectric layer 2270.

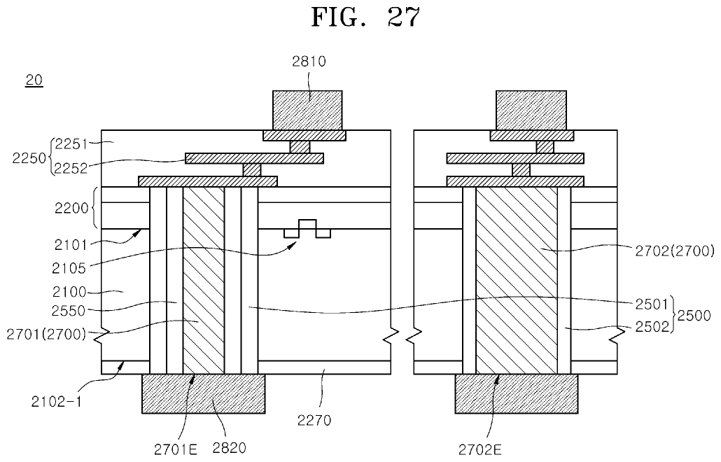

Referring to FIG. 27, second connecting portions 2820 may be formed to be electrically connected to the end portion 2701E of the first through via 2701 and the end portion 2702E of the second through via 2702. Each of the second connecting portions 2820 may be formed in a shape of a conductive bump. The conductive bump may be formed of a conductive material including copper (Cu). Although the second connecting portions 2820 are described as conductive bumps, the shape of each of the second connecting portions 2820 is not be limited to the shape of a conductive bump, Each of the second connecting portions 2820 may be formed in a shape of a conductive pad, for example.

By the above-described process, the semiconductor device 20 according to another embodiment may be implemented. The semiconductor device 20 may include the first and second through vias 2701 and 2702 having different widths W25 and W24, respectively.

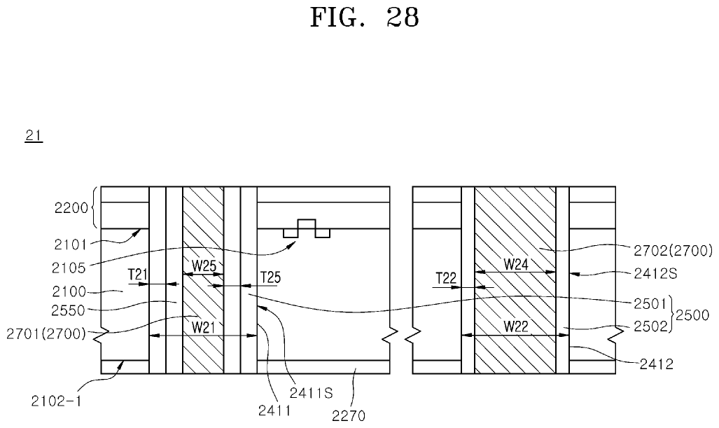

FIG. 28 is a schematic diagram illustrating a semiconductor device 21 according to another embodiment of the present disclosure. Referring to FIG, 28, the semiconductor device 21 according to another embodiment may include a first through via 2701 and a second through via 2702 that substantially penetrate a substrate 2100. The substrate 2100 may include a first via hole 2411 and a second via hole 2412. The first and second via holes 2411 and 2412 may be formed as through holes extending from a first surface 2102 of the substrate 2100 to a second surface 2102-1 on the opposite side.

The first and second through vias 2701 and 2702 may extend from the first surface 2101 of the substrate 2100 to the second surface 2102-1 on the opposite side. The first through via 2701 may be formed in the first via hole 2411, and the second through via 2702 may be formed in the second via hole 2412. A first insulating layer first portion 2501 and a second insulating layer 2550 may be formed to overlap with each other at an interface between a sidewall surface 2411S of the first via hole 2411 and the first through via 2701. A first insulating layer second portion 2502 may be formed at an interface between a sidewall surface 2412S of the second via hole 2412 and the second through via 2702.

A first width W21 of the first via hole 2411 may be substantially the same as a second width W22 of the second via hole 2412. Because a first thickness T21 of the first insulating layer first portion 2501 is substantially the same as a second thickness T22 of the first insulating layer second portion 2502, the second thickness T22 of the first insulating layer second portion 2502 may be thinner than an integrated thickness T21+T25 of the overlapping first insulating layer first portion 2501 and second insulating layer 2550. Accordingly, a fourth width W24 of the second through via 2702 may be wider than a fifth width W25 of the first through via 2701. The second through via 2702 may have the substantially wider width than the first through via 2701 by twice the third thickness T25 of the second insulating layer 2550.

Although not illustrated in FIG. 28, the first and second connecting portions 2810 and 2820 as shown in FIG. 27 may be electrically connected to the first and second through vias 2701 and 2702 of the semiconductor device 21. Alternatively, through vias of other semiconductor devices may be directly coupled to the first and second through vias 2701 and 2702 of the semiconductor device 21. When another semiconductor device is stacked over the semiconductor device 21 by a direct bonding method, such as hybrid bonding or wafer bonding, the first and second connecting portions 2810 and 2820 may be omitted.

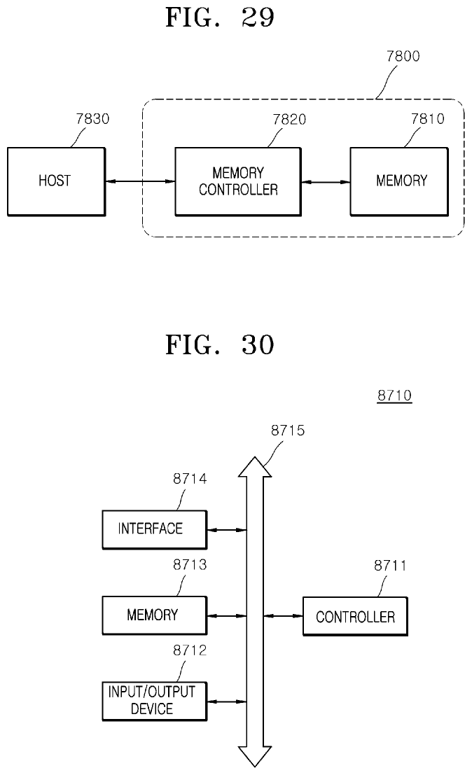

FIG. 29 is a block diagram illustrating an electronic system including a memory card 7800 employing at least one semiconductor device according to an embodiment of the present disclosure. The memory card 7800 includes a memory device 7810, such as a nonvolatile memory device, and a memory controller 7820. The memory device 7810 and the memory controller 7820 may store data or read out the stored data. At least one of the memory device 7810 and the memory controller 7820 may include at least one semiconductor package according to an embodiment of the present disclosure.

The memory device 7810 may include a nonvolatile memory device to which the technology of the embodiments of the present disclosure is applied. The memory controller 7820 may control the memory device 7810 such that stored data is read out or data is stored in response to a read/write request from a host 7830.

FIG. 30 is a block diagram illustrating an electronic system 8710 including at least one semiconductor device according to an embodiment of the present disclosure. The electronic system 8710 may include a controller 8711, an input/output device 8712, and a memory device 8713. The controller 8711, the input/output device 8712, and the memory device 8713 may be coupled with one another through a bus 8715 providing a path through which data move.

In an embodiment, the controller 8711 may include one or more of a microprocessor, digital signal processor, microcontroller, and/or logic device capable of performing the same functions as these components. The controller 8711 or the memory device 8713 may include at least one semiconductor package according to an embodiment of the present disclosure. The input/output device 8712 may include at least one selected among a keypad, a keyboard, a display device, a touchscreen, and so forth. The memory 8713 may be a device for storing data. The memory device 8713 may store data and/or commands to be executed by the controller 8711, and the like.

The memory device 8713 may include volatile memory, such as DRAM, and/or include nonvolatile memory, such as flash memory. For example, a flash memory device may be mounted to an information processing system such as a mobile terminal or a desktop computer. The flash memory device may constitute a solid state disk (SSD). In this case, the electronic system 8710 may stably store a large amount of data in a flash memory system.

The electronic system 8710 may further include an interface 8714 configured to transmit and receive data to and from a communication network. The interface 8714 may be a wired or wireless type. For example, the interface 8714 may include an antenna or a wired or wireless transceiver.

The electronic system 8710 may be realized as a mobile system, a personal computer, an industrial computer, or a logic system performing various functions. For exarnple, the mobile system may be any one of a personal digital assistant (PDA), a portable computer, a tablet computer, a rnobile phone, a smart phone, a wireless phone, a laptop computer, a memory card, a digital music system, and an information transmission/reception system.

If the electronic system 8710 is equipment capable of performing wireless communication, the electronic system 8710 may be used in a communication system by using a technique of CDMA (code division multiple access), GSM (global system for mobile communications), NADC (north American digital cellular), E-TDMA (enhanced-time division multiple access), WCDMA (wideband code division multiple access), CDMA2000, LTE (long term evolution), or Wibro (wireless broadband Internet).

The present teachings have been disclosed in conjunction with some embodiments as described above. Those skilled in the art will appreciate that various modifications, additions, and/or substitutions are possible, without departing from the scope and spirit of the present disclosure. Accordingly, the embodiments disclosed in the present specification should be considered from not a restrictive standpoint but an illustrative standpoint. The scope of the present teachings is not limited to the above descriptions but defined by the accompanying claims, and all of distinctive features in the equivalent scope should be construed as being included in the present teachings.

What is claimed is:

1. A method of manufacturing a semiconductor device, the method comprising:
forming first and second via holes in a substrate;
forming an insulating layer including a first portion and a second portion, the first portion narrowing the first via hole to a third via hole and the second portion narrowing the second via hole to a fourth via hole;
reducing a thickness of the second portion of the insulating layer to increase a width of the fourth via hole; and
forming a first through via and a second through via, the first through via filling the third via hole and the second through via filling the fourth via hole of increased width.

2. The method of claim 1, wherein the first via hole has the same width as the second via hole.

3. The method of claim 1, wherein the insulating layer is formed such that:
the first portion of the insulating layer covers a sidewall surface of the first via hole, and
the second portion of the insulating layer covers a sidewall surface of the second via hole.

4. The method of claim 1, wherein the insulating layer is formed such that the first portion of the insulating layer has substantially the same thickness as the second portion of the insulating layer.

5. The method of claim 1, wherein reducing the thickness of the second portion of the insulating layer includes:
forming a shielding pattern that shields the first portion of the insulating layer while leaving the second portion of the insulating layer exposed; and
recessing a portion of the second portion of the insulating layer left exposed by the shielding pattern.

6. The method of claim 5, wherein the shielding pattern is formed to fill the third via hole while leaving the fourth via hole open.

7. The method of claim 5, wherein the shielding pattern includes a photoresist pattern.

8. The method of claim 1, wherein the fourth via hole of increased width has a wider width than the third via hole.

9. The method of claim 1, wherein the second through via has a wider width than the first through via.

10. The method of claim 1, wherein the second through via has a wider width than the first through via by twice the reduced thickness of the second portion of the insulating layer.

11. The method of claim 1, wherein forming the first through via and the second through via includes:
forming a conductive layer filling the third and fourth via holes; and
planarizing the conductive layer to separate the conductive layer into the first through via filling the third via hole and the second through via filling the fourth via hole.

12. The method of claim 11, wherein the conductive layer includes copper (Cu).

13. The method of claim 1, further comprising recessing a portion of the substrate and exposing end portions of the first through via and the second through via after forming the first through via and the second through via.

14. The method of claim 1, wherein the insulating layer includes silicon dioxide.

15. A semiconductor device comprising:
a substrate including a first via hole and a second via hole;
a first through via disposed in the first via hole;
a second through via disposed in the second via hole;
an insulating layer first portion disposed between a side all surface of the first via hole and the first through via; and
an insulating layer second portion disposed between a sidewall surface of the second via hole and the second through via,
wherein the insulating layer second portion is thinner than the insulating layer first portion, and
wherein the second through via is wider than the first through via.

16. The semiconductor device of claim 15, wherein the second through via is wider width than the first through via by twice a difference in thickness between the insulating layer second portion and the insulating layer first portion,

17. The semiconductor device of claim 15, wherein the first via hole and the second via hole have the same width.

18. The semiconductor device of claim 15, wherein each of the insulating layer second portion and the insulating layer first portion includes silicon oxide.

19. The semiconductor device of claim 15, wherein each of the first through via and the second through via includes a copper (Cu) layer.
